(19) United States
(12) Patent Application Publication
(10) Pub. No.: US 2006/0103940 A1
(43) Pub. Date: May 18, 2006

(54) Method for configuring luminous zones and circuit zones of pixels of the display

(75) Inventors: Shin-Tai Lo, Miaoli County (TW); Yi-Chin Lin, Taichung City (TW)

Correspondence Address: BIRCH STEWART KOLASCH & BIRCH, PO BOX 747, FALLS CHURCH, VA, 22040-0747, US

(73) Assignee: WINTEK CORPORTATION

(21) Appl. No.: 10/986,217

(22) Filed: Nov. 12, 2004

(51) Int. Cl. H01L 29/45; H01L 29/74; H01L 31/111; G02B 27/10

(52) U.S. Cl. 359/619

(57) ABSTRACT

A method for configuring luminous zones and circuit zones of pixels eliminates the black lines problem occurred to the displaying picture caused by the layout of the circuit zones. The invention adopts the stripe layout but has the circuit zones and luminous zones of the active display device forming an image by inversion at 180 degrees such that the circuit zones and luminous zones of neighboring pixels are laid in staggered fashion, so that the circuit zones are not laid on the same straight line to prevent the displaying picture to be divided by black lines.

### FIELD OF THE INVENTION

The present invention relates to a method for configuring luminous zones and circuit zones of pixels of the display and particularly to a stripe pixel layout method for configuring luminous zones and circuit zones of pixels of an active-matrix type display device.

### BACKGROUND OF THE INVENTION

Conventional pixel layouts of display devices can be divided into the stripe layout type in FIG. 1, the mosaic layout type in FIG. 2 and the delta layout type in FIG. 3. The stripe layout, referring to FIG. 1, arranges red sub-pixel (R), green sub-pixel (G), blue sub-pixel (B) sequentially in row direction. The sub-pixels of the same column display the same color.

Conventional active display devices mostly adopt the stripe layout. It is easier, neat, and simple to configure, and does not require complicated layout and wiring. Thus it is widely used in TFT-LCD or TFT-OLED. While it may be configured easily in a uniform manner with the transistors laid on the same straight line, the circuit zones and the luminous zones are divided and separated clearly. Namely, the present stripe layout of R, G, and B pixels is built on a circuit layout (such as data line 11 and scan line 12) without taking into account of the effects of the circuit zones 14 and luminous zones 13. Refer to FIG. 4 for a conventional stripe layout. The circuit zones 14 of each row form dark areas that do not generate light. As a result, the picture with dark lines will be observed. This affects the picture quality of the display device.

Hence the display device that adopts the stripe layout often has zebra streaks of clear bright and dark segmentations formed by the luminous zones 13 and non-luminous zones (circuit zones 14). When the area of the transistors or capacitors of the circuit zones 14 increases, the dark line formed by the circuit zones 14 is especially obvious. Although the layout is simple and can display characters with a desired effect, the layout of neat straight line streaks makes images with dark lines resulting from the circuit zones. Namely, the non-luminous areas are noticeable.

The conventional delta or mosaic layout for R, G and B pixels also do not take into account of the layout of the circuit zones 14 and luminous zones 13. They directly shift the entire R, G and B pixels (referring to FIG. 5) to achieve even image display. Namely, the luminous zones 13 and circuit zones 14 are moved together. The non-luminous areas are also noticeable.

### SUMMARY OF THE INVENTION

Therefore the primary object of the present invention is to provide a method that adopts stripe layout and eliminates the noticeable black lines of the displayed image to improve the image quality of display devices and maintain the desired capability for displaying characters at the same time.

In order to eliminate the black lines problem occurred to the displaying picture caused by the layout of the circuit zones, the invention adopts the stripe layout but has the circuit zones and luminous zones of the active display device forming an image by inversion at 180 degrees such that the circuit zones and luminous zones of neighboring pixels are laid in staggered fashion, and the neighboring pixels that were originally laid orderly in straight lines can complement one another by preventing the circuit zones from being located on the same straight line of the same column, thereby the problem of the displaying picture being divided by black lines may be eliminated.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a conventional stripe layout for pixels.

FIG. 2 is a schematic view of a conventional mosaic layout for pixels.

FIG. 3 is a schematic view of a conventional delta layout for pixels.

FIG. 4 is a schematic view of a conventional stripe layout included wiring.

FIG. 5 is a schematic view of a conventional delta layout including luminous zones and circuit zones of pixels.

FIG. 6 is a schematic view of a layout of luminous zones and circuit zones of pixels of the invention.

FIG. 7 is a schematic view of a layout of the invention with the luminous zones and circuit zones of pixels in a ratio of 50:50.

FIG. 8 is a schematic view of another layout of the invention with the luminous zones and circuit zones of pixels in a ratio of 33:67.

FIG. 9 is a schematic view of an embodiment of the layout of the luminous zones and circuit zones of pixels and a wiring pattern of the invention.

FIG. 10 is a schematic view of another embodiment of the layout of the luminous zones and circuit zones of pixels and a wiring pattern of the invention.

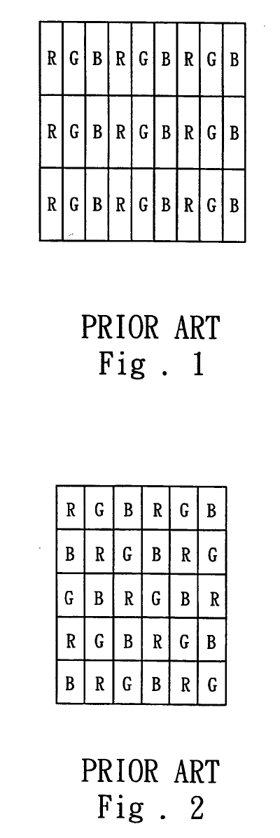

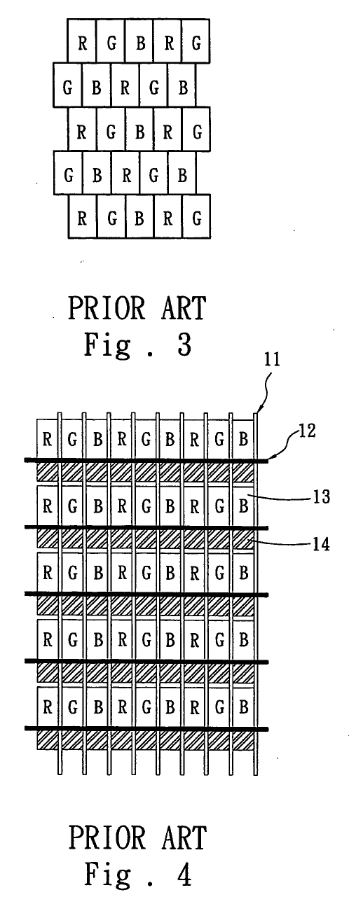

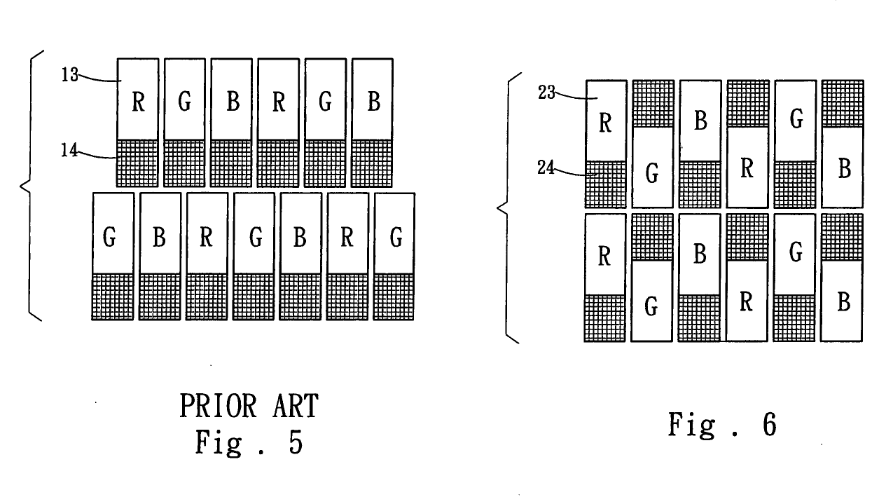

### DETAILED DESCRIPTION OF THE PREFERRED EMBODIMENTS

Please refer to FIG. 6 for a layout of pixel luminous zones 23 and circuit zones 24 of the invention. In order to achieve uniform color distribution and disperse the sensible characteristics of the same nature, all non-luminous zones (circuit zones 24) are dispersed. Namely, on the display device formed with a stripe layout, the luminous zones 23 and circuit zones 24 of the pixels of two neighboring columns are formed in images by inversion at 180 degrees such that the luminous zones 23 and the circuit zones 24 are laid evenly in a staggered manner. In other words, the arrangements of the luminous zones and the circuit zones of the R pixels and the neighboring G pixels are inverted against one other by 180 degrees, and the ones of the G pixels and the neighboring B pixels are inverted against one other by 180 degrees, and so on. Thereby the black lines occurred to the display device formed in the stripe layout are divided by pixel luminous zones 23. Then the luminous zones of pixels mix up with the non-luminous zones (circuit zones 24), which makes the picture evenly display and diminishes the division effect caused by the black lines resulting from the circuit zones 24.

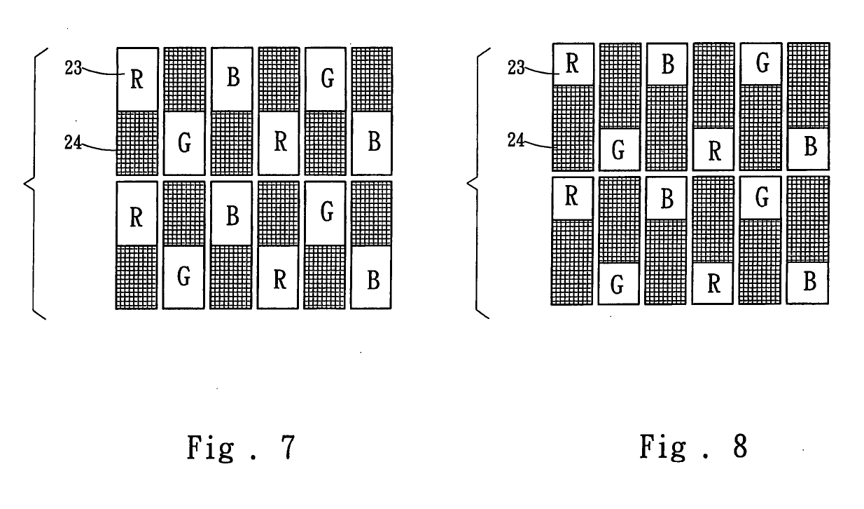

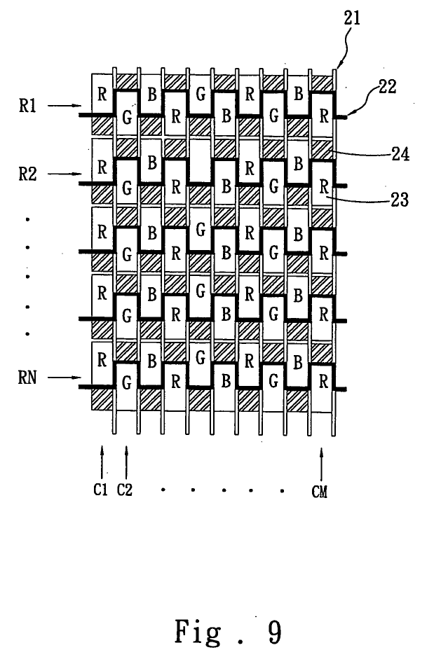

Furthermore, when the transistor or capacitor area of the circuit zone 24 increases, the ratio of the luminous zones 23 and circuit zones 24 may be altered to 50:50 and 33:67 and the layouts by the invention are shown in FIGS. 7 and 8.

Refer to FIG. 9 for an embodiment of the layout of the luminous zones 23 and circuit zones 24 of pixels and a wiring pattern of the invention. The pixels of two neighboring columns are formed in images by inversion at 180 degrees so that the luminous zones 23 and circuit zones 24 of pixels are laid in a staggered manner to generate even display. The arrangements of the luminous zones and the circuit zones of the R pixels and the neighboring G pixels are inverted against one other by 180 degrees, and the ones of the G pixels and the neighboring B pixels are inverted against one other by 180 degrees. Data lines 21 and scan lines 22 are laid along the circuit zones 24 as the conventional techniques do. The red (R) pixels are laid on the first column C1 on the left side, the green (G) pixels are laid on the second column C2 adjacent to column C1, and the luminous zones 23 and circuit zones 24 of these two columns are inverted by 180 degrees. Namely, through the layout of the pixels by inversion at 180 degrees, a set of pixels that complement with each other may be obtained (with the luminous zones 23 and circuit zones 24 of the pixels on the odd column fixed, the luminous zones 23 and circuit zones 24 of the pixels on the even column are inverted 180 degrees). By means of this approach, the luminous zones 23 and circuit zones 24 of the pixels on columns C2, C4, C6, C8 . . . CM are reconfigured by inverting for 180 degrees, then color pixels of R, G, and B are filled to form a layout that can generate even picture display. As shown in the drawing, the luminous zones 23 and circuit zones 24 on the same row (R1, R2, . . . , RN) also are staggered.

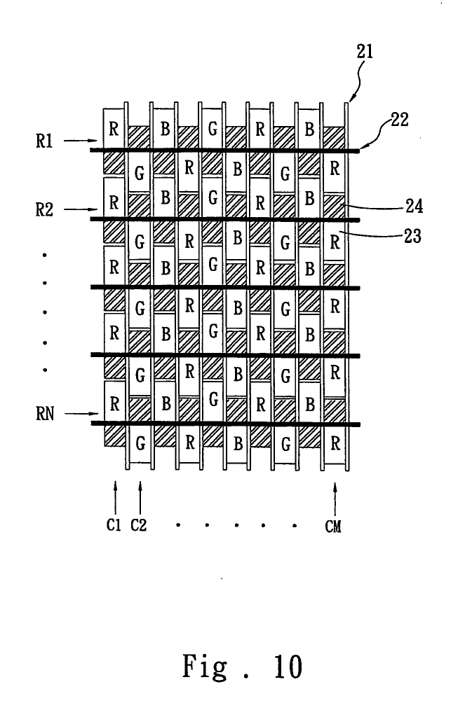

Moreover, the pixels of the same column may also be shifted vertically (the direction of data lines) at a distance same as the vertical distance of the circuit zone 24. The scan line 22 passing through the circuit zones 24 may be altered from the crank shapes shown in FIG. 9 to straight lines shown in FIG. 10. Such an arrangement makes layout design easier, and can reduce errors during photo mask checking and prevent uncontrollable conditions during profile depositing and etching processes. As the scan lines 22 and the data lines 21 are laid in vertical and horizontal manner, fabrication defect may be minimized.

For handsets, PDA or other portable electronic display devices, the requirement for displaying picture grows rapidly. It is predicted that in the future messages shown by picture will be more than the text messages. The invention provides a stripe layout with the luminous zones 23 and circuit zones 24 laid in a staggered manner and in images by inversion at 180 degrees to resolve the problem occurred to the conventional techniques that have the picture divided by dark lines. The resulting display picture is more uniform and improved character display may be achieved.

What is claimed is:

1. A method for configuring pixel luminous zones and circuit zones forming the pixel luminous zones and the circuit zones on a display device in a stripe layout, comprising steps of:
laying the pixel luminous zones and circuit zones on one column and the pixel luminous zones and circuit zones on a neighboring column in a layout of images by inversion at 180 degrees; and
forming the layout of the pixel luminous zones and the pixel circuit zones on the entire display device in a staggered fashion.

2. The method of claim 1, wherein the pixels on one column are shifted vertically so that scan lines passing through the circuit zones are adjusted and formed in straight lines.
